(19) United States
(12) Patent Application Publication
(10) Pub. No.: US 2006/0221564 A1
(43) Pub. Date: Oct. 5, 2006

(54) Display apparatus

(75) Inventor: Woo-Jung Kim, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/350,125

(22) Filed: Feb. 9, 2006

(30) Foreign Application Priority Data
Mar. 8, 2005 (KR) 2005-0019340

(51) Int. Cl. G06F 1/16; H05K 7/20

(52) U.S. Cl. 361/682; 361/688

(57) ABSTRACT

The present invention relates to a display apparatus, comprising a cathode ray tube for displaying images; a casing for accommodating and supporting the cathode ray tube; a substrate bracket comprising a first bracket and a second bracket spaced at a predetermined distance from the first bracket and provided in an upper part of the first bracket for coupling with the casing to be mounted in a lower part of the cathode ray tube; and an image circuit part comprising a first image circuit part mounted on the first bracket and a second circuit part mounted on the second bracket, and for displaying the images in the cathode ray tube. Thus, the present invention provides the display apparatus increased and efficient space utilization of the mounting structure of electrical parts according to thinness of the display apparatus and efficient heat dispersion.

### CROSS-REFERENCE TO RELATED APPLICATIONS

This application claims the benefit under 35 U.S.C.§ 119(a) of Korean Patent Application No. 2005-0019340, entitled “Display Apparatus,” filed on Mar. 8, 2005, the entire disclosure of which is hereby incorporated by reference.

### BACKGROUND OF INVENTION

1. Field of Invention

The present invention relates to a display apparatus. More particularly, the present invention relates to a display apparatus structure of circuit parts built in the display apparatus.

2. Description of the Related Art

Conventionally, a display apparatus refers to an electronic instrument such as a monitor and a television and the like that visually display data on the screen by using letters or figures and the like.

Recently, flat panel displays using a Liquid Crystal Display (LCD) and a Plasma Display Panel (PDP) have become popular because they are light weight and thin. Thus, the popularity of Cathode Ray Tube) displays has been decreasing.

However, the flat panel displays using the LCD and the PDP are expensive compared with CRT displays.

Therefore, recently, with the development of an electron beam deflection system, a thickness of the CRT display has decreased considerably, so that a display apparatus using a slim CRT is gaining in popularity.

Herein, the display apparatus of the slim CRT should be improved to increase space utilization corresponding to the mounting structure of various electrical parts used in the display apparatus according to the thickness of the CRT.

Further, a new case structure and electrical parts are needed for effectively removing heat generated due to the thinness of the display of the CRT by electrical parts.

### SUMMARY OF THE INVENTION

Accordingly, embodiments of the present invention provide a display apparatus for increasing the efficiency of space utilization by the mounting structure of electrical parts according to the thickness of a display apparatus and effectively capable of efficient heat release.

The foregoing and other objects are substantially realized by providing a display apparatus, comprising a cathode ray tube for displaying images; a casing for accommodating and supporting the cathode ray tube; a substrate bracket comprising a first bracket and a second bracket spaced at a predetermined distance from the first bracket and provided in an upper part of the first bracket, and coupling with the casing to be mounted in a lower part of the cathode ray tube; and an image circuit part comprising a first image circuit part mounted on the first bracket and a second circuit part mounted on the second bracket, and to display the images in the cathode ray tube.

The first image circuit part may comprise a system circuit part for converting an image signal input into a signal capable of being processed by the cathode ray tube.

The second image circuit part may comprise a deflection circuit part for deflecting an electron beam of the cathode ray tube based on the signal converted by the system circuit part to display the image in the cathode ray tube.

The deflection circuit part may comprise a horizontal pulse and a vertical pulse generation circuit part for generating horizontal and vertical pulses based on a horizontal frequency and a vertical frequency of the image signal, a dynamic yoke circuit part for deflecting the electron beam scanned into the cathode ray tube on the basis of the horizontal and vertical pulses output from the horizontal pulse and vertical pulse generation circuit part; and a high voltage generation circuit part for supplying a high voltage to the cathode ray tube.

The present invention further may comprise a power supply circuit part mounted on the first bracket, for supplying power to the cathode ray tube and the image circuit part.

The second bracket may be detachably provided in the first bracket.

The second bracket may comprise a base for mounting the second image circuit part and a supporting rib for coupling with the first bracket, and extended downward from the base.

Other objects, advantages, and salient features of the invention will become apparent from the detailed description, which, taken in conjunction with the annexed drawings, discloses embodiments of the invention.

### BRIEF DESCRIPTION OF THE DRAWINGS

These and other aspects, features, and advantages of certain embodiments of the present invention will be more apparent and more readily appreciated from the following detailed description, taken with reference to the accompanying drawings, in which:

FIG. 1 is a perspective view of a display apparatus in accordance with an embodiment of the present invention;

FIG. 2 is an exploded perspective view of the display apparatus in accordance with the embodiment of the present invention;

FIG. 3 is a perspective view illustrating a mounting structure of an image circuit part in accordance with the embodiment of the present invention; and

FIG. 4 is a sectional view schematically illustrating the mounting structure of the image circuit part in accordance with the embodiment of the present invention.

Throughout the drawings, the same drawing reference numerals will be understood to refer to the same elements, features, and structures.

### DETAILED DESCRIPTION OF EXEMPLARY EMBODIMENTS

The matters defined in the description such as a detailed construction and elements thereof, are provided to assist in a comprehensive understanding of the embodiments of the invention and are merely exemplary. Accordingly, those of ordinary skill in the art will recognize that various changes and modifications of the embodiments described herein can be made without departing from the scope and spirit of the invention.

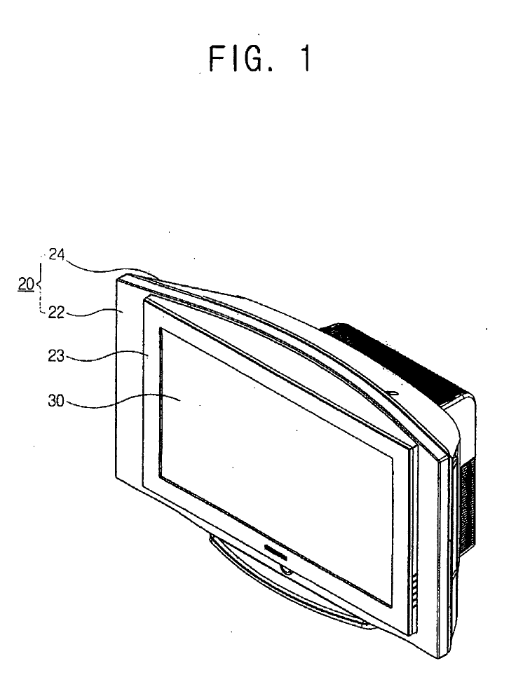

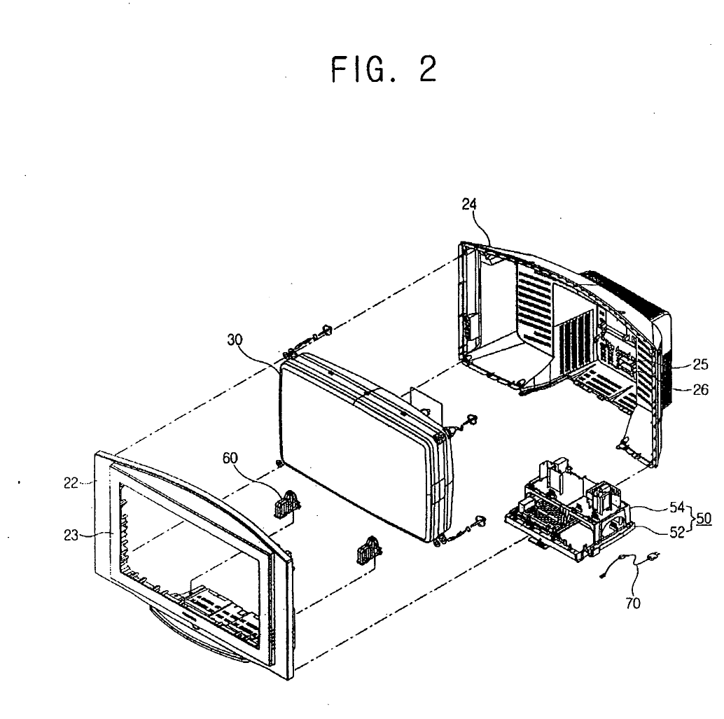

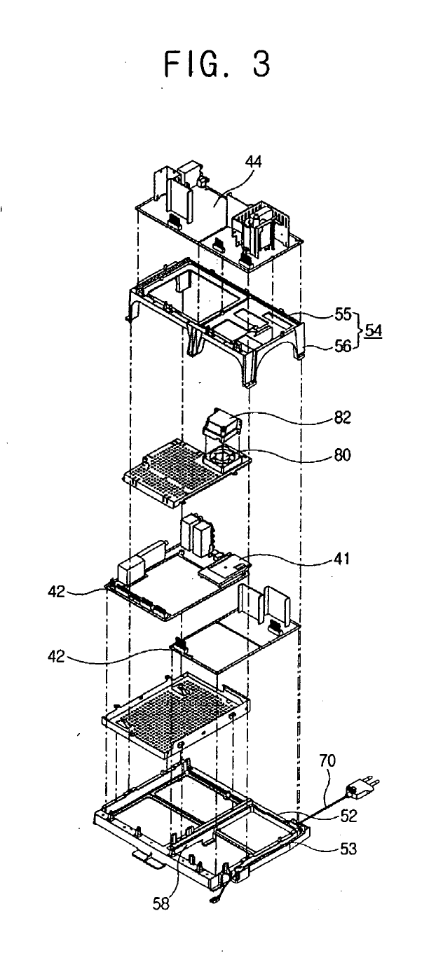

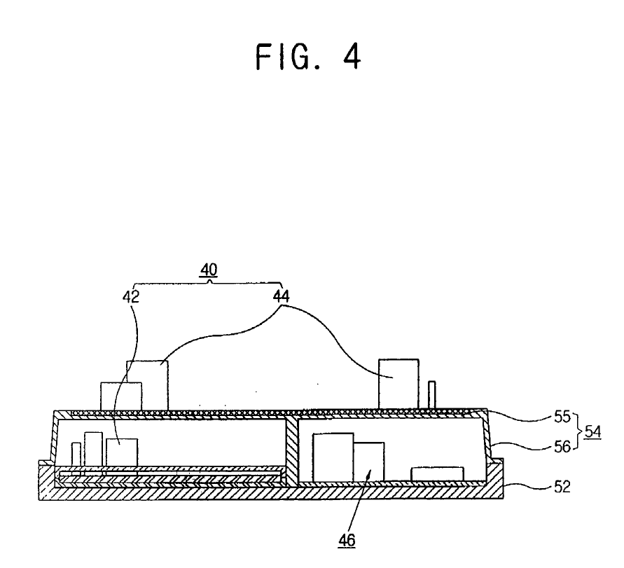

As shown in FIGS. 1 through 4, a display apparatus according to an embodiment of the present invention comprises a cathode ray tube 30 for displaying images, a casing 20 for accommodating and supporting the cathode ray tube 30, a substrate bracket 50 coupled with the casing 20 to be mounted in a lower portion of the cathode ray tube 30, and an image circuit part 40 mounted in the substrate bracket 50.

The casing 20 comprises a front cover 22 and a rear cover 24. The front cover 22 is provided in front of the cathode ray tube 30 and has an opening in the middle thereof to expose the cathode ray tube 30 to the outside. The rear cover 24 covers a rear of the cathode ray tube 30, and accommodates and supports the cathode ray tube 30 by coupling with the front cover 22.

Herein, the front of the front cover 22 is coupled with a cover mask 23 shaped approximately as a rectangle, and the rear cover 24 is provided with an air outlet 25 and a Point Of Deployment (POD) card insert hole 26.

The cathode ray tube 30 has a thin-type or slim-type structure, and is coupled in front of the casing 20 spaced from a bottom portion of the casing 20. The cathode ray tube 30 may employ alternative configurations.

Between the bottom of the casing 20 and a lower side of the cathode ray tube 30 are provided a pair of supporting members 60 spaced at a predetermined distance to stably support the cathode ray tube 30.

The substrate bracket 50 is mounted in order to raise the image circuit part 40, thereby increasing space utilization and providing a compact appearance for the casing 20. The substrate bracket 50 is mounted in the bottom of the casing 20, this is, a lower part of the cathode ray tube 30.

The substrate bracket 50 comprises a first bracket 52, and a second bracket 54 spaced at a predetermined distance from the first bracket 52 in an upper part of the first bracket 52. Herein, the second bracket 54 is detachably provided in the first bracket 52, thereby enhancing the assembly thereof. The first bracket 52 and the second bracket 54 are mounted to distribute electrical parts of the image circuit part 40, thereby maximizing space utilization thereof.

The image circuit part 40 comprises a first image part 42 mounted on the first bracket 52, and a second image circuit part 44 mounted on the second bracket 54. Accordingly, as described above, the electric parts comprising the image circuit part 40 are divided into the first image circuit part 42 and the second image circuit part 44, which are mounted and distributed on the first bracket 52 and the second bracket 54 of the substrate bracket 50 respectively, thereby efficiently increasing the space utilization.

In the display apparatus according to the embodiment of the present invention, the second image circuit part 44 mounted on the second bracket 54 may mount the electrical parts that generate a large amount of heat, thereby enhancing the heat dispersion efficiency.

For example, in the display apparatus according to the embodiment of the present invention, the second image circuit part 44 mounted on the second bracket 54 may comprise a deflection circuit part for deflecting an electron beam of the cathode ray tube 30 so as to display images in the cathode ray tube 30.

Herein, the deflection circuit part may comprise a horizontal pulse and vertical pulse generation circuit part for generating horizontal and vertical pulses based on horizontal and vertical frequencies of the image signal, a dynamic yoke circuit part for deflecting the electron beam scanned into the cathode ray tube 30 on the basis of the horizontal and vertical pulses output from the horizontal and vertical pulses generation circuit part, and a high voltage generation circuit part for supplying a high voltage to the cathode ray tube 30.

Further, the deflection circuit part is mounted on the second bracket 54, thereby minimizing the amount of high voltage wire required and minimizing the amount of distortion of a deflection signal.

Meanwhile, the first image circuit part 42 mounted on the first bracket 52 may comprise a system circuit part for converting an image signal input into a signal capable of being processed by the cathode ray tube 30. The system circuit part may comprise a micro computer to control the all display apparatus, a video processor for processing the image signal input, an audio processor for processing an audio signal input, an input terminal block for inputting the image signal and the audio signal, and a tuner.

On the first bracket 52 of the substrate bracket 50 may be mounted a power supply circuit part 46 for supplying power to the cathode ray tube 30 and the image circuit part 40. Herein, the power supply circuit part 46 mounted on the first bracket 52 may comprise a circuit configuration for supplying the conventional electrical power, for example, a switching mode power supply (SMPS), a bridge diode for converting A/C into D/C, a transformer, a multi regulator, and a micro computer for controlling the circuits.

In the first bracket 52 may be formed a cable supporter 53 for accommodating and supporting a power cable 70 for receiving A/C power from a power source.

The second bracket 54 comprises a base 55 for mounting the second image circuit part 44, and a supporting rib 56 for coupling with the first bracket 52 and extended downward from the base 55.

The supporting rib 56 can be variably adjusted or changed to stably mount the first image circuit part 42 and the power supply circuit part 46 mounted on the first bracket 52 between the first bracket 52 and the second bracket 54

Meanwhile, the first image circuit part 42 is provided with a POD card-mounting part 41 mounting the POD card (not shown) that is inserted through the POD card insert hole 26 formed in the rear cover 24. In an upper side of the POD card-mounting part 41 is mounted a POD fan 80 for discharging heat generated from the POD card (not shown) to the outside.

On the POD fan 80 is coupled a guide part 82 that guides heat ventilated via the POD fan 80 to the air outlet 25 formed in the rear cover 24.

As described above, the embodiment of the present invention provides the display apparatus increased and efficient space utilization of the mounting structure of electrical parts according to the thinness or slimness of the display apparatus and efficient heat dispersion.

While the invention has been shown and described with reference to a certain embodiment thereof, it will be understood by those skilled in the art that various changes in form and details may be made therein without departing from the spirit and scope of the invention as defined by the appended claims.

What is claimed is:

1. A display apparatus, comprising:
a cathode ray tube for displaying images;
a casing for accommodating and supporting the cathode ray tube;
a substrate bracket comprising a first bracket and a second bracket spaced at a predetermined distance from the first bracket and provided in an upper part of the first bracket for coupling with the casing and mounted in a lower part of the cathode ray tube; and
an image circuit part comprising a first image circuit part mounted on the first bracket and a second circuit part mounted on the second bracket for displaying the images in the cathode ray tube.

2. The display apparatus according to claim 1, wherein the first image circuit part comprises a system circuit part for converting an input image signal into a signal capable of being processed by the cathode ray tube;
the second image circuit part comprises a deflection circuit part for deflecting an electron beam of the cathode ray tube based on the signal converted by the system circuit part for displaying the image in the cathode ray tube.

3. The display apparatus according to claim 2, wherein the deflection circuit part comprises a horizontal pulse and vertical pulse generation circuit part for generating horizontal and vertical pulses based on horizontal and vertical frequencies of the image signal;
a dynamic yoke circuit part for deflecting the electron beam scanned into the cathode ray tube on the basis of the horizontal and vertical pulses output from the horizontal and vertical pulses generation circuit part; and
a high voltage generation circuit part for supplying a high voltage to the cathode ray tube.

4. The display apparatus according to claim 3, further comprising a power supply circuit part mounted on the first bracket for supplying power to the cathode ray tube and the image circuit part.

5. The display apparatus according to claim 1, wherein the second bracket is detachably provided in the first bracket.

6. The display apparatus according to claim 1, wherein the second bracket comprises a base for mounting the second image circuit part and a supporting rib coupling with the first bracket, and extended downward from the base.

7. The display apparatus according to claim 1, wherein the casing further comprises a front cover and a rear cover.

8. The display apparatus according to claim 1, wherein the cathode ray tube comprises a thin cathode ray tube.

9. The display apparatus according to claim 7, wherein the front cover has an opening for displaying a front portion of the cathode ray tube.

10. The display apparatus according to claim 7, wherein the rear cover accommodates and supports the cathode ray tube by coupling with the front cover.

11. The display apparatus according to claim 7, wherein the rear cover comprises an air outlet and a Point of Deployment (POD) card insert hole for allowing heat to be dispersed via a fan.

12. The display apparatus according to claim 2, wherein the deflection circuit part is mounted on the second bracket in order to minimize an amount of high voltage wire required and an amount of distortion of a deflection signal
